(19) United States
(12) Patent Application Publication
(10) Pub. No.: US 2021/0300272 A1
(43) Pub. Date: Sep. 30, 2021

(54) PRESENTATION DEVICE, PRESENTATION METHOD, AND PROGRAM

(71) Applicant: HONDA MOTOR CO., LTD., Minato-ku, Tokyo (JP)

(72) Inventor: Yoshikazu Nishida, Wako-shi (JP)

(21) Appl. No.: 17/262,231

(22) PCT Filed: Aug. 8, 2019
(86) PCT No.: PCT/JP2019/031377

§ 371 Date: Jan. 22, 2021

(30) Foreign Application Priority Data
Aug. 28, 2018 (JP) 2018-159085

(51) Int. Cl. B60R 16/04; H01M 10/48; H02J 7/00; B60R 16/033; G01R 31/371

(52) U.S. Cl. CPC B60R 16/04; H01M 10/48; G01R 31/371; B60R 16/033; H02J 7/00034

(57) ABSTRACT

A presentation device includes an acquirer configured to acquire information representing degrees of deterioration in a plurality of secondary batteries mounted in each of a plurality of vehicles including a target vehicle, a deriver configured to derive a relative degree of deterioration in the secondary battery mounted in the target vehicle among a plurality of secondary batteries that satisfy a predetermined condition with respect to the secondary battery mounted in the target vehicle, and a presenter configured to present the relative degree of deterioration to a user of the target vehicle.

### TECHNICAL FIELD

The present invention relates to a presentation device, a presentation method, and a program.

Priority is claimed on Japanese Patent Application No. 2018-159085, filed Aug. 28, 2018, the content of which is incorporated herein by reference.

### BACKGROUND ART

There are electric vehicles equipped with a travel motor and hybrid vehicles equipped with a travel motor and an engine. The motor mounted in these vehicles is driven with the electric power supplied from a secondary battery such as a battery. A malfunction such as a decrease in an amount of charge due to deterioration may occur in the secondary battery. However, if the accuracy of detection of the degree of deterioration in the secondary battery is low, it becomes difficult to find a malfunction such as a decrease in the amount of charge. Therefore, technology for accurately determining the degree of deterioration in a secondary battery has been proposed (see, for example, Patent Document 1).

### CITATION LIST

### Patent Document

[Patent Document 1]

Japanese Unexamined Patent Application, First Publication No. 2015-162991

### SUMMARY OF INVENTION

### Technical Problem

However, when the degree of deterioration in a secondary battery is determined in an own vehicle, even if the degree of deterioration can be determined accurately, it is a determination only for the degree of deterioration in the own vehicle. Thus, even if the degree of deterioration in the secondary battery determined using the above-described technology is presented to the user, it is difficult for the user to determine whether or not the secondary battery is being used in a usage state in which it is difficult to allow the progress of deterioration.

The present invention has been made in consideration of such circumstances and an objective of the present invention is to provide a presentation device, a presentation method, and a program capable of allowing a user to appropriately determine a usage state of a secondary battery.

### Solution to Problem

According to the present invention, a presentation device, a presentation method, and a program adopt the following configurations.

(1): According to an aspect of the present invention, there is provided a presentation device including: an acquirer configured to acquire information representing degrees of deterioration in a plurality of secondary batteries mounted in each of a plurality of vehicles including a target vehicle; a deriver configured to derive a relative degree of deterioration in the secondary battery mounted in the target vehicle among a plurality of secondary batteries that satisfy a predetermined condition with respect to the secondary battery mounted in the target vehicle; and a presenter configured to present the relative degree of deterioration to a user of the target vehicle.

(2): In the above-described aspect (1), the relative degree of deterioration is a deviation value of the degree of deterioration in the secondary battery mounted in the target vehicle from the degree of deterioration in each of the plurality of secondary batteries.

(3): In the above-described aspect (1) or (2), the predetermined condition is that the secondary batteries are secondary batteries of the same type.

(4): In the above-described aspect (1) or (2), the predetermined condition is that the secondary batteries are secondary batteries of the same type mounted in vehicles of the same type.

(5): In any one of the above-described aspects (1) to (4), the presenter is configured to present the relative degree of deterioration to a user of the target vehicle by causing the relative degree of deterioration to be displayed on a display provided in the target vehicle.

(6): According to an aspect of the present invention, there is provided a presentation method including: acquiring, by a computer, information representing degrees of deterioration in a plurality of secondary batteries mounted in each of a plurality of vehicles including a vehicle; deriving, by the computer, the relative degree of deterioration in the secondary battery mounted in the target vehicle among a plurality of secondary batteries that satisfy a predetermined condition with respect to the secondary battery mounted in the target vehicle; and presenting, by the computer, the relative degree of deterioration to a user of the target vehicle.

(7): According to an aspect of the present invention, there is provided a program for causing a computer to: acquire information representing degrees of deterioration in a plurality of secondary batteries mounted in each of a plurality of vehicles including a vehicle; derive a relative degree of deterioration in the secondary battery mounted in the target vehicle among a plurality of secondary batteries that satisfy a predetermined condition with respect to the secondary battery mounted in the target vehicle; and present the relative degree of deterioration to a user of the target vehicle.

### Advantageous Effects of Invention

According to the aspects (1) to (7), it is possible to allow a user to appropriately determine the usage state of a secondary battery.

### BRIEF DESCRIPTION OF DRAWINGS

FIG. 1 is a diagram showing an example of a configuration of a presentation system 1.

FIG. 2 is a diagram showing an example of a configuration of a vehicle 10.

FIG. 3 is a diagram showing an example of a configuration of an interior of the vehicle 10.

FIG. 4 is a flowchart showing an example of a flow of a process executed by parts of a center server 100.

FIG. 5 is a flowchart showing an example of a flow of a process executed by parts of the center server 100.

FIG. 6 is a conceptual diagram of a process of generating a capacity estimation model 156.

FIG. 7 is a conceptual diagram of a process of generating the capacity estimation model 156 following FIG. 6.

FIG. 8 is a histogram showing an example of a distribution of degrees of deterioration in batteries mounted in vehicles 10 in a market.

### DESCRIPTION OF EMBODIMENTS

Hereinafter, embodiments of a presentation device, a presentation method, and a program according to the present invention will be described with reference to the drawings. Although a vehicle 10 is assumed to be an electric vehicle in the following description, it is only necessary for the vehicle 10 to be a vehicle equipped with a secondary battery for supplying electric power for traveling or the vehicle 10 may be a hybrid vehicle or a fuel cell vehicle.

### First Embodiment

### [Overall Configuration]

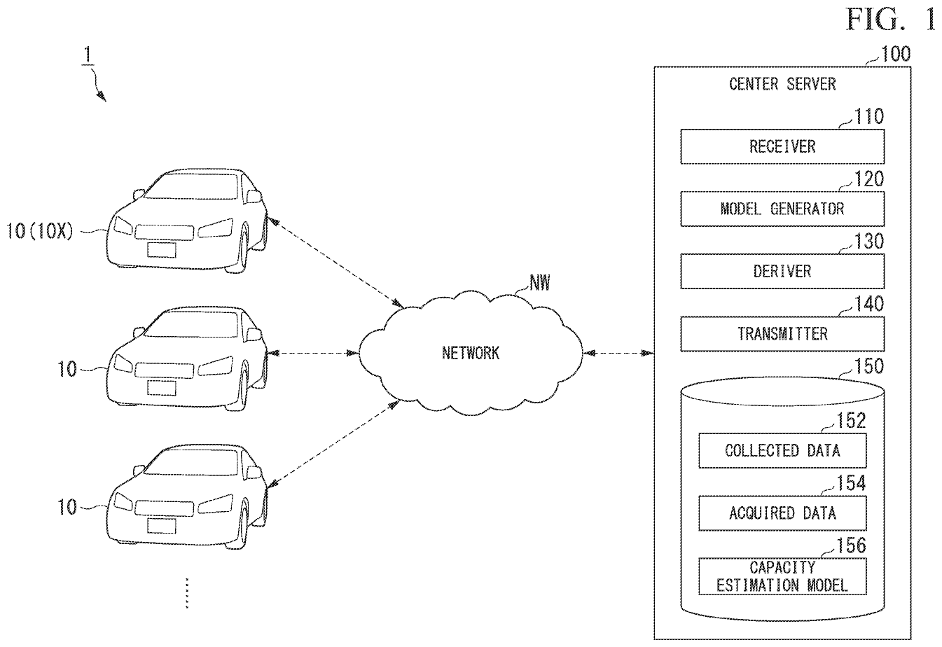

FIG. 1 is a diagram showing an example of a configuration of a presentation system 1. The presentation system 1 is a system for presenting a deviation value of a degree of deterioration (a relative degree of deterioration) in a battery (a secondary battery) mounted in a vehicle (hereinafter referred to as a “target vehicle”) 10X among a plurality of vehicles 10. As shown in FIG. 1, the presentation system 1 includes the plurality of vehicles 10 and a center server (a presentation device) 100. The center server 100 diagnoses the battery mounted in the target vehicle 10X on the basis of information transmitted from the plurality of vehicles 10.

The center server 100 obtains the relative degree of deterioration in the battery mounted in the target vehicle 10X from the market on the basis of a battery diagnosis result and presents the obtained relative degree of deterioration to a user of the target vehicle 10X. Also, the market refers to an area in which there are vehicles that provide data for obtaining a deviation value of a degree of deterioration and refers to an area determined on the basis of appropriate conditions such as a geographical condition and a quantitative condition. Also, the target vehicle 10X is one of the plurality of vehicles 10. The vehicle 10 and the center server 100 communicate with each other via a network NW. The network NW includes, for example, the Internet, a wide area network (WAN), a local area network (LAN), a provider device, a radio base station, and the like.

### [Vehicle 10]

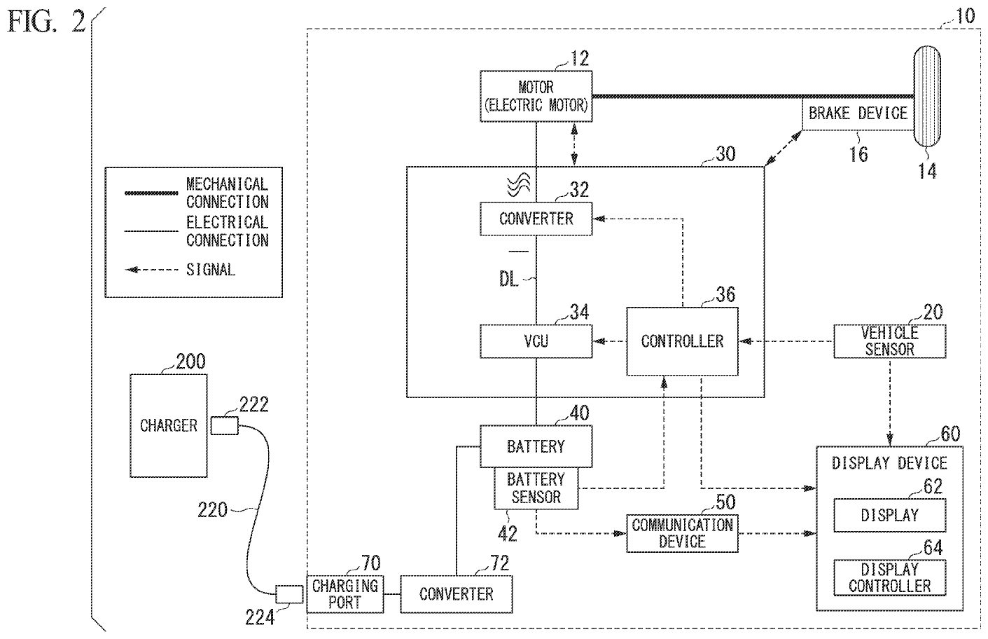

FIG. 2 is a diagram showing an example of the configuration of the vehicle 10. As shown in FIG. 2, the vehicle 10 includes, for example, a motor 12, drive wheels 14, a brake device 16, a vehicle sensor 20, a power control unit (PCU) 30, a battery 40, a battery sensor 42 such as a voltage sensor, and an electric current sensor, and a temperature sensor, a communication device 50, a display device 60, a charging port 70, and a converter 72.

The motor 12 is, for example, a three-phase alternating current (AC) motor. A rotor of the motor 12 is connected to the drive wheels 14. The motor 12 outputs motive power to the drive wheels 14 using the supplied electric power. Also, the motor 12 generates electric power using kinetic energy of the vehicle at the time of deceleration of the vehicle.

The brake device 16 includes, for example, a brake caliper, a cylinder configured to transfer hydraulic pressure to the brake caliper, and an electric motor configured to generate hydraulic pressure in the cylinder. The brake device 16 may include a mechanism configured to transfer the hydraulic pressure generated by an operation of a brake pedal to the cylinder via a master cylinder as a backup. Also, the brake device 16 is not limited to the above-described configuration and may be an electronically controlled hydraulic brake device configured to transfer the hydraulic pressure of the master cylinder to the cylinder.

The vehicle sensor 20 include, for example, an accelerator opening degree sensor, a vehicle speed sensor, a brake depression amount sensor, and the like. The accelerator opening degree sensor is attached to an accelerator pedal which is an example of an operation element for receiving an acceleration instruction from a driver, detects an amount of operation of the accelerator pedal, and outputs the detected amount of operation as an accelerator opening degree to the controller 36. The vehicle speed sensor includes, for example, a wheel speed sensor and a speed calculator attached to each wheel and combines wheel speeds detected by wheel speed sensors to derive the speed of the vehicle (a vehicle speed) and output the derived speed to the controller 36 and the display device 60. The brake depression amount sensor is attached to the brake pedal, detects an amount of operation of the brake pedal by the driver, and outputs the detected amount of operation as an amount of brake depression to the controller 36.

The PCU 30 includes, for example, a converter 32, a voltage control unit (VCU) 34, and the controller 36. Also, a configuration in which these components are integrated as the PCU 34 is only an example and these components may be arranged in a distributed manner.

The converter 32 is, for example, an AC-direct current (DC) converter. A DC-side terminal of the converter 32 is connected to a DC link DL. The battery 40 is connected to the DC link DL via the VCU 34. The converter 32 converts an AC of electric power generated by the motor 12 into a DC and outputs the DC to the DC link DL.

The VCU 34 is, for example, a DC-DC converter. The VCU 34 boosts electric power supplied from the battery 40 and outputs the boosted electric power to the DC link DL.

The controller 36 includes, for example, a motor controller, a brake controller, and a battery/VCU controller. The motor controller, the brake controller, and the battery/VCU controller may be replaced with separate control devices such as a motor ECU, a brake ECU, and a battery ECU.

The motor controller controls the motor 12 on the basis of an output of the vehicle sensor 20. The brake controller controls the brake device 16 on the basis of the output of the vehicle sensor 20. The battery/VCU controller calculates a state of charge (SOC) (hereinafter also referred to as a “battery charge rate”) of the battery 40 on the basis of the output of the battery sensor 42 attached to the battery 40, and outputs the calculated SOC to the VCU 34 and the display device 60. The VCU 34 increases the voltage of the DC link DL in accordance with an instruction from the battery/VCU control.

For example, the battery 40 is a secondary battery such as a lithium ion battery. The battery 40 stores electric power introduced from the charger 200 outside the vehicle 10 and is discharged for traveling of the vehicle 10. The battery sensor 42 include, for example, a current sensor, a voltage sensor, and a temperature sensor. The battery sensor 42 detect, for example, the electric current value, the voltage value, and the temperature of the battery 40. The battery sensor 42 output the electric current value, the voltage value, the temperature, and the like that have been detected to the controller 36 and the communication device 50.

The communication device 50 includes a radio module for connecting to a cellular network or a Wi-Fi network. The communication device 50 acquires battery usage status information such as the electric current value, the voltage value, and the temperature output from the battery sensor 42, and transmits the battery usage status information to the center server 100 via the network NW shown in FIG. 1. The communication device 50 adds battery type information and vehicle type information of the own vehicle to the battery usage status information to be transmitted. Also, the communication device 50 receives the information transmitted from the center server 100 via the network NW. The communication device 50 outputs the received information to the display device 60.

The display device 60 includes, for example, a display 62 and a display controller 64. The display 62 displays information according to control of the display controller 64. The display controller 64 causes the display 62 to display a deviation value of a degree of deterioration in the battery in accordance with the information output from the controller 36 and the communication device 50. Also, the display controller 64 causes the display 62 to display a vehicle speed or the like output from the vehicle sensor 20.

The charging port 70 is provided directed outside of a vehicle body of the vehicle 10. The charging port 70 is connected to the charger 200 via a charging cable 220. The charging cable 220 includes a first plug 222 and a second plug 224. The first plug 222 is connected to the charger 200 and the second plug 224 is connected to the charging port 70. Electricity supplied from the charger 200 is supplied to the charging port 70 via the charging cable 220.

Also, the charging cable 220 includes a signal cable attached to the power cable. The signal cable mediates communication between the vehicle 10 and the charger 200. Therefore, each of the first plug 222 and the second plug 224 includes a power connector and a signal connector.

The converter 72 is provided between the battery 40 and the charging port 70. The converter 72 converts an electric current introduced from the charger 200 via the charging port 70, for example, an AC, into a DC. The converter 72 outputs the DC obtained through the conversion to the battery 40.

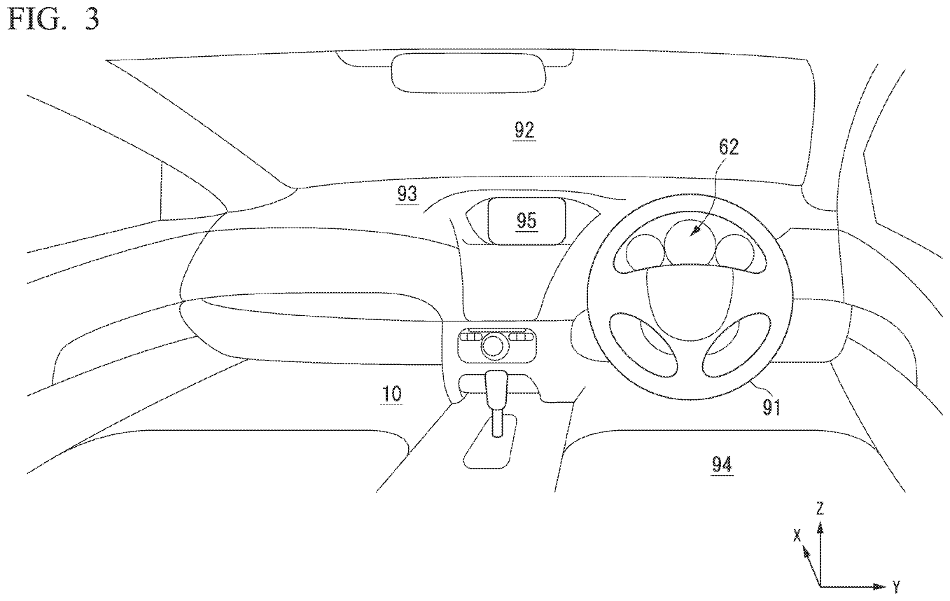

FIG. 3 is a diagram showing the configuration of an interior of the vehicle 10. As shown in FIG. 2, the vehicle 10 includes, for example, a steering wheel 91 for controlling the steering of the vehicle 10, a front windshield 92 for separating the outside and the inside of the vehicle, and an instrument panel 93. The front windshield 92 is a member having optical transparency.

Also, the display 62 of the display device 60 is provided near the front of the driver's seat 94 on the instrument panel 93 in the interior of the vehicle. The display 62 can be visually recognized by the driver through a gap of the steering wheel 91 or through the steering wheel 91. Also, a second display device 95 is provided at the center of the instrument panel 93. The second display device 95 displays, for example, an image corresponding to a navigation process executed by a navigation device (not shown) mounted in the vehicle 10 or displays a video of a communication partner and the like on a videophone. Also, the second display device 95 may display a television program, play a DVD, or display content such as a downloaded movie.

### [Center Server 100]

The center server 100 shown in FIG. 1 includes, for example, a receiver (an acquirer) 110, a model generator 120, a deriver 130, a transmitter (a presenter) 140, and a storage 150. The model generator 120 and the deriver 130 are implemented by, for example, a hardware processor such as a central processing unit (CPU) executing a program (software). Some or all of these components may be implemented by hardware (including a circuit unit; circuitry) such as a large scale integration (LSI) circuit, an application specific integrated circuit (ASIC), a field-programmable gate array (FPGA), or a graphics processing unit (GPU) or may be implemented by software and hardware in cooperation. The program may be pre-stored in a storage device (a storage device having a non-transient storage medium) such as a hard disk drive (HDD) or a flash memory or may be stored in a removable storage medium (a non-transient storage medium) such as a DVD or a CD-ROM and installed when the storage medium is mounted in a drive device. The storage 150 is implemented by the storage device described above.

The receiver 110 receives information indicating a degree of deterioration in the battery such as an electric current value, a voltage value, a temperature, or total elapsed usage time of the battery transmitted from each of the plurality of vehicles 10. The receiver 110 causes the storage 150 to store the received information as collected data 152 for each piece of identification information of the vehicle 10 (for example, license plate information, communication identification information of the communication device 50, identification information of a registered user, or the like). Battery type information or vehicle type information may be added to the collected data 152.

Under an assumption that the process of the center server 100 is performed, each of the plurality of vehicles 10 detects an electric current value, a voltage value, and a temperature of the battery 40 using the battery sensor 42 and the electric current value, the voltage value, and the temperature of the battery 40 are transmitted as the battery usage status information from the communication device 50 to the center server 100. The vehicle 10 may perform the transmission of the battery usage status information every predetermined time interval, for example, every hour or every day, or may perform the transmission of the battery usage status information on the basis of an instruction of the user of the vehicle 10. Also, the vehicle 10 may perform the transmission of the battery usage status information in response to a request of the center server 100. Also, when a predetermined condition is satisfied, for example, when the battery load exceeds a certain amount, or when an increased amount of the battery load from the previous transmission becomes a certain amount, the vehicle 10 may be configured to transmit battery usage status information. Also, the vehicle 10 may transmit the battery usage status information at any one or more of these timings.

The model generator 120 calculates and acquires a battery capacity on the basis of the electric current value, the voltage value, and the temperature of the battery received by the receiver 110 and stored as the collected data 152 in the storage 150 and causes the storage 150 to store the acquired battery capacity as acquired data 154. Similar to the collected data 152, the acquired data 154 may include battery type information and vehicle type information added thereto.

The model generator 120 performs machine learning using the data stored in the storage 150 as learning data and training data and generates a capacity estimation model 156. The model generator 120 uses the electric current value, the voltage value, the temperature, and the total elapsed usage time stored as the collected data 152 in the storage 150 as the learning data. The model generator 120 uses the battery capacity (the degree of deterioration in the battery) stored as the acquired data 154 in the storage 150 as the teacher data. Because the battery capacity decreases as the battery deteriorates, the battery capacity becomes an index indicating the degree of deterioration in the battery.

For example, the model generator 120 generates a neural network model of all markets for batteries having the input of data (an electric current value I, a voltage value V, a temperature T, and total elapsed usage time) related to batteries of the same type (a plurality of secondary batteries satisfying a predetermined condition) and having the output of a battery capacity as the capacity estimation model 156. The model generator 120 causes the storage 150 to store the generated capacity estimation model 156. The model generator 120 integrates outputs of the capacity estimation model 156 when the capacity estimation model 156 is generated.

The deriver 130 generates a battery capacity distribution of the batteries mounted in the plurality of vehicles 10 in the market using an integration value of the capacity estimation model 156 obtained through the integration by the model generator 120. The deriver 130 causes the storage 150 to store the generated battery capacity distribution. Also, the deriver 130 reads the battery capacity (hereinafter referred to as a “target battery capacity”) estimated on the basis of the collected data 152 transmitted from the target vehicle 10X and the battery capacity distribution from the storage 150. The deriver 130 derives a deviation value of the degree of deterioration (a relative degree of deterioration) in the battery mounted in the target vehicle 10X among the batteries mounted in the plurality of vehicles 10 in the market on the basis of the target battery capacity and the battery capacity distribution that have been read. The deriver 130 outputs the derived deviation value to the transmitter 140.

The transmitter 140 transmits the deviation value output from the deriver 130 to the target vehicle 10X and presents the deviation value to the user of the target vehicle 10X via the target vehicle 10X.

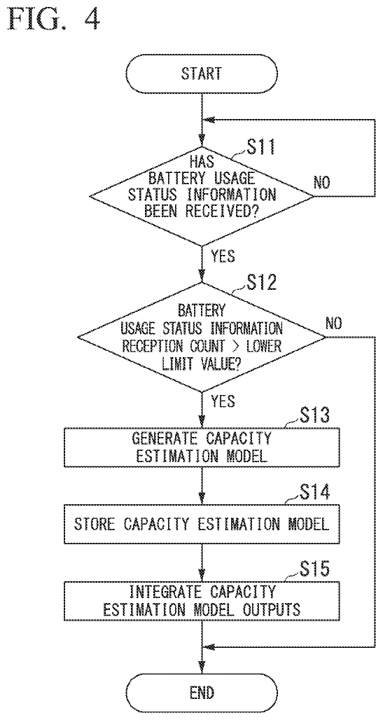

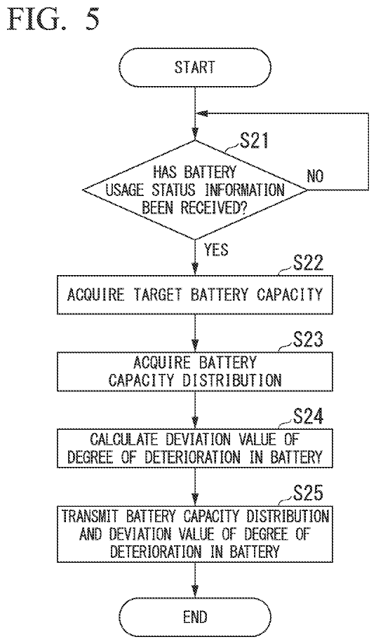

Next, a process of the center server 100 will be described in more detail. FIGS. 4 and 5 are flowcharts showing an example of a flow of a process executed by parts of the center server 100. A process of generating the capacity estimation model 156 in the center server 100 will be described with reference to FIG. 4 and a process of deriving the deviation value of the degree of deterioration in the battery in the center server 100 will be described with reference to FIG. 5.

As shown in FIG. 4, when the capacity estimation model 156 is generated, the center server 100 first determines whether or not the receiver 110 has received battery usage status information transmitted from the plurality of vehicles 10 (step S11). When it is determined that the receiver 110 has not received the battery usage status information (step S11: NO), the center server 100 iterates the processing of step S11.

When it is determined that the receiver 110 has received the battery usage status information (step S11: YES), the center server 100 determines whether or not a battery usage status information reception count exceeds a lower limit value (step S12). The lower limit value of the battery usage information reception count is the number of data elements required to generate the capacity estimation model 156 and an appropriate number can be set. The center server 100 can generate an accurate capacity estimation model 156 as the battery usage information reception count increases. Thus, the center server 100 may set the number of data elements from which the capacity estimation model 156 can be generated with predetermined accuracy as the lower limit value of the battery usage status information reception count. Also, after the battery usage status information reception count exceeds the lower limit value, the determination of step S12 may be omitted.

When it is determined that the battery usage status information reception count does not exceed the lower limit value (step S12: NO), the center server 100 ends the process shown in FIG. 4 as it is. When it is determined that the battery usage status information reception count exceeds the lower limit value (step S12: YES), the model generator 120 of the center server 100 generates the capacity estimation model 156 (step S13). For example, the model generator 120 may generate the capacity estimation model 156 as follows.

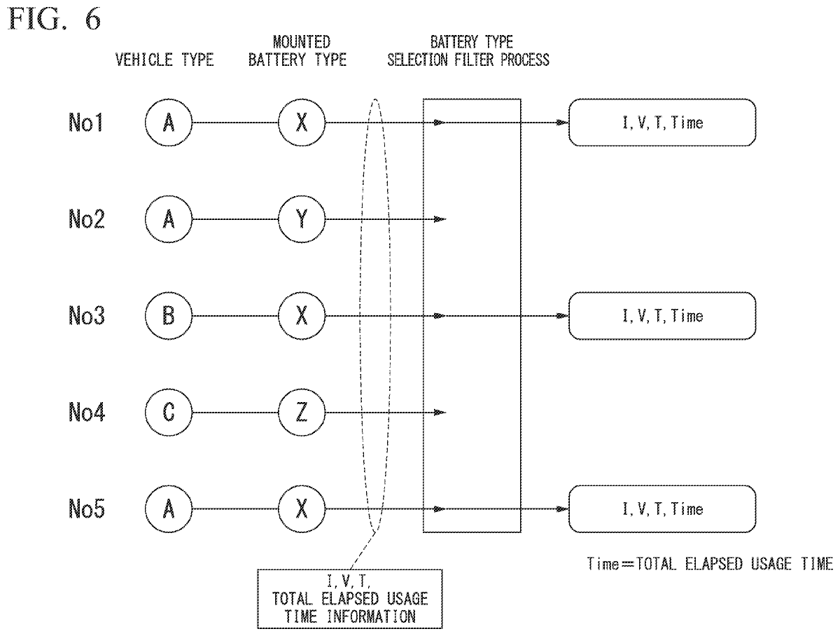

FIG. 6 is a conceptual diagram of a process of generating the capacity estimation model 156. As shown in FIG. 6, the model generator 120 applies battery usage status information (an electric current value (I), a voltage value (V), and a temperature (T)) and data of total elapsed usage time (Time) included in the collected data 152 to a battery type selection filter. In the example shown in FIG. 6, data is provided from vehicles of Nos. 1 to 5.

The model generator 120 selects the collected data 152 on the basis of the battery type information and the vehicle type information added to the collected data 152. The model generator 120 may select the collected data 152 on the basis of the battery type information or may select the collected data 152 on the basis of the battery type information and the vehicle type information. The model generator 120 selects battery usage status information and total elapsed usage times of batteries of the same type (or batteries of the same type mounted in vehicles of the same type) using the battery type selection filter. In the example shown in FIG. 6, battery usage statuses and total elapsed usage times for batteries of an “X” type are selected. Thus, although five battery usage statuses and total elapsed usage times of Nos. 1 to 5 are shown in FIG. 6, the model generator 120 selects three data elements of Nos. 1, 3, and 5 as information of the batteries of the “X” type.

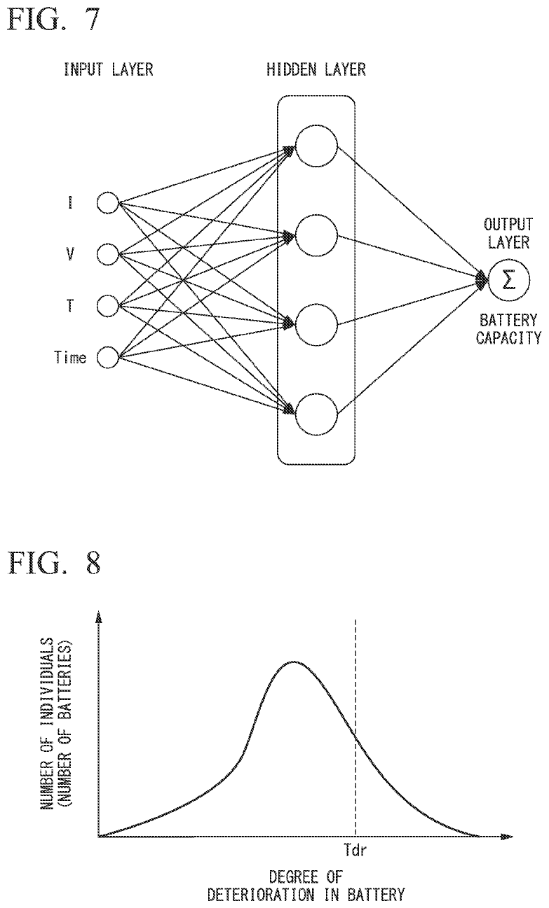

FIG. 7 is a conceptual diagram of a process of generating the capacity estimation model 156 following FIG. 6. As shown in FIG. 7, the model generator 120 generates the capacity estimation model 156 having an input layer, a hidden layer, and an output layer. The electric current value (I), the voltage value (V), the temperature (T), and the total elapsed usage time (Time), which are items of the battery usage status information, are input to the input layer. The battery capacity is output from the output layer. The hidden layer has a multi-layer neural network connecting the input layer and the output layer. Parameters of the hidden layer are optimized by performing machine learning using the input to the input layer as learning data and using data to be output from the output layer as teacher data.

The model generator 120 generates (updates) the capacity estimation model 156 by performing machine learning in which the battery usage status information and the total elapsed usage time selected in FIG. 6 are input to the input layer. Thus, the model generator 120 generates the capacity estimation model 156 of batteries of each type, for example, the batteries of the “X” type, and causes the storage 150 to store the capacity estimation model 156.

Returning to the flow shown in FIG. 4, the center server 100 generates the capacity estimation model 156 in the model generator 120. Subsequently, the model generator 120 causes the storage 150 to store the generated capacity estimation model 156 (step S14). Also, the center server 100 integrates outputs when the capacity estimation model 156 is generated and causes the storage 150 to store an integration result (step S15). Thus, the center server 100 ends the process shown in FIG. 4.

Next, a process of deriving the deviation value of the degree of deterioration in the battery will be described with reference to FIG. 5. As shown in FIG. 5, when the deviation value of the degree of deterioration in the battery is derived, the center server 100 first determines whether or not the receiver 110 has received battery usage status information transmitted from a plurality of vehicles 10 (step S21). When it is determined that the receiver 110 has not received the battery usage status information (step S21: NO), the center server 100 iterates the processing of step S21.

When it is determined that the receiver 110 has received the battery usage status information (step S21: YES), the center server 100 acquires a target battery capacity (step S22). The deriver 130 of the center server 100 acquires the target battery capacity by reading the target battery capacity estimated on the basis of the battery usage status information stored in the storage 150 as collected data transmitted from the target vehicle 10X from the storage 150.

Subsequently, the deriver 130 of the center server 100 acquires the battery capacity distribution by reading the battery capacity distribution stored in the storage 150 (step S23). The deriver 130 calculates a deviation value of the degree of deterioration in the battery on the basis of the target battery capacity acquired in step S22 and the battery capacity distribution acquired in step S23 (step S24).

FIG. 8 is a histogram showing an example of a distribution of degrees of deterioration in batteries mounted in vehicles 10 in the market. The battery capacity distribution obtained in step S22 is represented by, for example, the histogram shown in FIG. 8 and the number of batteries mounted in the vehicles 10 having degrees of deterioration in a predetermined number of batteries is represented as the number of individuals (the number of batteries).

On the other hand, a degree of deterioration Tdr in the battery of the target vehicle 10X is indicated by a broken line in FIG. 8. The deriver 130 obtains an average value, a variance, and a standard deviation in the degree of deterioration in the battery from a distribution of degrees of deterioration in the battery shown in FIG. 8. Using the average value, the variance, the standard deviation, and the degree of deterioration in the battery of the target vehicle 10X, the deviation value of the degree of change in the battery mounted in the target vehicle 10X is calculated.

After the deviation value of the degree of deterioration in the battery mounted in the target vehicle 10X is calculated, the transmitter 140 of the center server 100 transmits the battery capacity distribution and the deviation value of the degree of deterioration in the battery to the target vehicle 10X (step S25). Thus, the transmitter 140 of the center server 100 presents the battery capacity distribution and the deviation value of the degree of deterioration in the battery. Also, the center server 100 may omit the transmission of the battery capacity distribution. Thus, the center server 100 ends the process shown in FIG. 5.

The target vehicle 10X receives the battery capacity distribution and the deviation value of the degree of deterioration in the battery transmitted from the center server 100 in the communication device 50 shown in FIG. 1. The communication device 50 outputs the received battery capacity distribution and the received deviation value of the degree of deterioration in the battery to the display device 60. For example, the display controller 64 of the display device 60 causes the display 62 to display the battery capacity distribution and the deviation value of the degree of deterioration in the battery. As for the battery capacity distribution, for example, the histogram shown in FIG. 8 may be displayed as it is. Alternatively, the battery capacity distribution may be displayed in other forms. Also, the deviation value of the degree of deterioration in the battery may be displayed by a numerical value, a graph, or the like. Thus, the presentation system 1 presents the battery capacity distribution of the batteries mounted in the vehicles 10 in the market and the deviation value of the degree of deterioration in the battery mounted in the target vehicle 10X to the user of the target vehicle 10X.

According to the above-described embodiment, the deriver 130 of the center server 100 generates a battery capacity distribution and obtains the deviation value of the degree of deterioration in the battery mounted in the target vehicle 10X from the target battery capacity and the battery capacity distribution. Thus, the center server 100 presents a relative degree of deterioration in the battery mounted in the target vehicle 10X as the deviation value in comparison with a plurality of batteries mounted in the plurality of vehicles 10 in the market. The presented deviation value is transmitted to the target vehicle 10X and presented to the user via the target vehicle 10X. Thus, the user can recognize whether his/her usage state is superior or inferior to the average battery usage state in the market so that the deterioration in the battery is prevented. Therefore, the user can be allowed to appropriately determine the usage state of the battery.

Also, in the above-described embodiment, the relative degree of deterioration presented to the user is a deviation value. Thus, the user can easily recognize a difference from other users with respect to the usage state of the battery. Also, the center server 100 uses data of batteries of the same type when the relative degree of deterioration in the battery is obtained. Thus, because comparisons are made between batteries of the same type, the relative degree of deterioration can be derived with high accuracy. Further, the center server 100 uses data of batteries of the same type mounted in vehicles of the same type when determining the relative degree of deterioration in the battery. Thus, because comparisons are made between batteries of the same type mounted in vehicles of the same type, the relative degree of deterioration can be derived more accurately. Also, the derived degree of deterioration in the battery is displayed and presented on the display 62 in the display device 60 of the target vehicle 10X. Thus, the user can recognize the relative degree of deterioration in the battery while he or she is in the target vehicle 10X.

Also, although the center server 100 transmits the battery capacity distribution and the deviation value of the degree of deterioration in the battery to the target vehicle 10X in the above-described example, the deviation value of the degree of deterioration in the battery may be calculated in the target vehicle. In this case, the target vehicle 10X calculates the degree of deterioration in the battery on the basis of detection values of the battery sensors 42 and calculates a deviation value of the degree of deterioration in the battery of the own vehicle from the battery capacity transmitted from the center server 100 and the calculated degree of deterioration in the battery.

Also, although the “plurality of secondary batteries satisfying the predetermined condition” are batteries 40 of the same type in the above-described embodiment, other conditions may be used. For example, the “plurality of secondary batteries satisfying the predetermined condition” may be batteries 40 of the same type mounted in vehicles of the same type. Also, the “predetermined condition” may be a geographical condition as in a case of batteries mounted in each of a plurality of vehicles 10 in the market or the predetermined condition may be another condition. The “predetermined condition” may be a time condition as in a case in which a time period when the battery status information is detected by the battery sensor 42 is from 7:00 to 19:00 or the like.

Also, although the “relative degree of deterioration” is set as the deviation value in the above-described embodiment, a degree other than the deviation value may be used as long as it is a relative degree. For example, the “relative degree of deterioration” may be included in the top 10% of all comparative targets or may be a degree of deviation from an average value or a representative value such as a mode value or a median value.

Also, although the “presentation” of the relative degree of deterioration is performed via the display 62 of the display device 60 mounted in the target vehicle 10X in the above-described embodiment, the “presentation” of the relative degree of deterioration may be performed in other forms. For example, the “presentation” may be performed by being displayed on a display of an information terminal (a portable terminal) owned by the user or the “presentation” may be performed by emitting a sound from a speaker provided in the target vehicle 10X or the information terminal.

Also, although the degree of deterioration in the battery 40 mounted in the vehicle 10 is calculated and acquired by the model generator 120 in the above-described embodiment, the degree of deterioration in the battery 40 mounted in the vehicle 10 may be acquired in other forms. For example, the vehicle 10 may calculate a battery capacity on the basis of the electric current value, the voltage value, and the temperature of a battery and transmit the calculated battery capacity as the degree of deterioration in the battery to the center server 100.

Although modes for carrying out the present invention have been described above using the embodiments, the present invention is not limited to the embodiments and various modifications and replacements can be applied without departing from the spirit and scope of the present invention.

### REFERENCE SIGNS LIST

1 Presentation system

10 Vehicle

10X Target vehicle

12 Motor

50 Communication device

55 Derivation device

60 Display device

62 Display

64 Display controller

70 Charging port

93 Instrument panel

94 Driver's seat

95 Second display device

100 Center server (presentation device)

110 Receptor (acquirer)

120 Model generator

130 Deriver

140 Transmitter (presenter)

200 Charger

NW Network

What is claim is:

1. A presentation device comprising:
an acquirer configured to acquire information representing degrees of deterioration in a plurality of secondary batteries mounted in each of a plurality of vehicles including a target vehicle;
a deriver configured to derive a relative degree of deterioration in the secondary battery mounted in the target vehicle among a plurality of secondary batteries within an area defined based on at least one of a geographical condition, a quantitative condition, or a time condition with respect to the secondary battery mounted in the target vehicle; and
a presenter configured to present the relative degree of deterioration to a user of the target vehicle.

2. The presentation device according to claim 1, wherein the relative degree of deterioration is a deviation value of the degree of deterioration in the secondary battery mounted in the target vehicle from the degree of deterioration in each of the plurality of secondary batteries.

3. The presentation device according to claim 1, wherein the predetermined condition is that the secondary batteries are secondary batteries of the same type.

4. The presentation device according to claim 1, wherein the predetermined condition is that the secondary batteries are secondary batteries of the same type mounted in vehicles of the same type.

5. The presentation device according to claim 1, wherein the presenter is configured to present the relative degree of deterioration to the user of the target vehicle by causing the relative degree of deterioration to be displayed on a display provided in the target vehicle.

6. A presentation method using a computer, comprising:
acquiring, by a computer, information representing degrees of deterioration in a plurality of secondary batteries mounted in each of a plurality of vehicles including a vehicle;
deriving, by the computer, a relative degree of deterioration in the secondary battery mounted in the target vehicle among a plurality of secondary batteries within an area defined based on at least one of a geographical condition, a quantitative condition, or a time condition with respect to the secondary battery mounted in the target vehicle; and
presenting, by the computer, the relative degree of deterioration to a user of the target vehicle.

7. A computer-readable non-transitory storage medium that stores a program, the program causing a computer to:
acquire information representing degrees of deterioration in a plurality of secondary batteries mounted in each of a plurality of vehicles including a vehicle;
derive a relative degree of deterioration in the secondary battery mounted in the target vehicle among a plurality of secondary batteries within an area defined based on at least one of a geographical condition, a quantitative condition, or a time condition a with respect to the secondary battery mounted in the target vehicle; and
present the relative degree of deterioration to a user of the target vehicle.
